(19) United States
(12) Patent Application Publication
(10) Pub. No.: US 2021/0182521 A1
(43) Pub. Date: Jun. 17, 2021

(54) DISPLAY DEVICE WITH FINGERPRINT IDENTIFICATION FUNCTION

(71) Applicant: WUHAN CHINA STAR OPTOELECTRONICS SEMICONDUCTOR DISPLAY TECHNOLOGY CO., LTD, Wuhan (CN)

(72) Inventor: Xiaoliang FENG, Wuhan (CN)

(73) Assignee: WUHAN CHINA STAR OPTOELECTRONICS SEMICONDUCTOR DISPLAY TECHNOLOGY CO., LTD, Wuhan (CN)

(21) Appl. No.: 16/470,249

(22) PCT Filed: Feb. 13, 2019
(86) PCT No.: PCT/CN2019/074957

§ 371 Date: Jun. 17, 2019

(51) Int. Cl. G06K 9/00

(52) U.S. Cl. CPC G06K 9/0002; G06F 3/041

(57) ABSTRACT

A display device with a fingerprint identification function includes a display panel including a display area and a non-display area; and an ultrasonic fingerprint identification module disposed inside an upper surface of the display device with the fingerprint identification function, and including a substrate; a reflecting layer disposed on the substrate; a plurality of microcrystalline particles distributed in the reflecting layer; and an ultrasonic generating and receiving unit disposed on a side of the reflecting layer.

### FIELD OF INVENTION

The present disclosure relates to the field of display devices, and more particularly, to a display device with a fingerprint identification function.

### BACKGROUND OF INVENTION

Phones usually use front buttons (such as IPHONEs) or back capacitance (such as ANDROID phones) to realize fingerprint identification. However, with demands of full screens and ultra-thin phones, a space for design of fingerprint identification in the phones is increasingly limited, therefore all kinds of embedded fingerprint identification technologies are developed to adapt to full screens, such as an ultrasonic mode under a screen or an optic mode with grating effects.

However, the above technologies increase thicknesses of the phones, therefore solutions need to be provided to solve problem in existing technologies.

### SUMMARY OF INVENTION

An object of the present disclosure is to provide a display device with a fingerprint identification function to solve the problem of increased thickness of a phone caused by an ultrasonic mode under a screen or an optic mode with grating effects in the existing technologies.

To achieve the above object, an embodiment of the present disclosure provides a display device with a fingerprint identification function. The display device includes a display panel including a display area and a non-display area; and an ultrasonic fingerprint identification module disposed inside an upper surface of the display device with the fingerprint identification function, and including a substrate; a reflecting layer disposed on the substrate; a plurality of microcrystalline particles distributed in the reflecting layer; and an ultrasonic generating and receiving unit disposed on a side of the reflecting layer. A distribution area of the plurality of microcrystalline particles correspond to the display area of the display panel, and a diameter of each of the microcrystalline particles ranges between 0.01 and 3 micrometers.

In an embodiment of the present disclosure, the ultrasonic generating and receiving unit corresponds to the non-display area of the display panel.

In an embodiment of the present disclosure, the display device further includes a plurality of ultrasonic generating and receiving units disposed on two sides of the reflecting layer.

In an embodiment of the present disclosure, a number of the plurality of microcrystalline particles increases with increasing distance from the ultrasonic generating and receiving unit.

In an embodiment of the present disclosure, a number of the plurality of microcrystalline particles decreases with increasing distance from the ultrasonic generating and receiving unit.

To achieve the above object, an embodiment of the present disclosure provides a display device with a fingerprint identification function. The display device includes a display panel including a display area and a non-display area; and an ultrasonic fingerprint identification module disposed inside an upper surface of the display device with the fingerprint identification function, and including a substrate; a reflecting layer disposed on the substrate; a plurality of microcrystalline particles distributed in the reflecting layer; and an ultrasonic generating and receiving unit disposed on a side of the reflecting layer.

In an embodiment of the present disclosure, a distribution area of the plurality of microcrystalline particles correspond to the display area of the display panel.

In an embodiment of the present disclosure, a diameter of each of the microcrystalline particles ranges between 0.01 and 3 micrometers.

In an embodiment of the present disclosure, the ultrasonic generating and receiving unit corresponds to the non-display area of the display panel.

In an embodiment of the present disclosure, the display device further includes a plurality of ultrasonic generating and receiving units disposed on two sides of the reflecting layer.

In an embodiment of the present disclosure, a number of the plurality of microcrystalline particles increases with increasing distance from the ultrasonic generating and receiving unit.

In an embodiment of the present disclosure, a number of the plurality of microcrystalline particles decreases with increasing distance from the ultrasonic generating and receiving unit.

To achieve the above object, an embodiment of the present disclosure provides a display device with fingerprint identification function. The display device includes a display panel including a display area and a non-display area; and an ultrasonic fingerprint identification module embedded in the display panel, and including a reflecting layer disposed in the display panel; a plurality of microcrystalline particles distributed in the reflecting layer; and an ultrasonic generating and receiving unit disposed on a side of the reflecting layer.

In an embodiment of the present disclosure, the display panel includes a first layer; a second layer disposed on the first layer and configured to display an image together with the first layer; and a touch layer disposed on the second layer and configured to sense signals applying on the display panel.

In an embodiment of the present disclosure, the display device further includes a polarizer disposed on the ultrasonic fingerprint identification module; and a protective layer disposed on the polarizer.

Compared to the existing technologies, in the display device with the fingerprint identification function of the present disclosure, the ultrasonic generating and receiving unit is disposed on the side of the reflecting layer, which decreases the thickness of the display device. Furthermore, the distribution area of the plurality of microcrystalline particles correspond to the display area of the display panel, which realizes a design of a full screen.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a side view of an ultrasonic fingerprint identification module according to an embodiment of the present disclosure.

FIG. 2 is a top view of a display device with a fingerprint identification function according to an embodiment of the present disclosure.

FIG. 3 is a diagram that illustrates ultrasonic waves generated by an ultrasonic generating and receiving unit are reflected by a microcrystalline particle according to an embodiment of the present disclosure.

FIG. 4 is a diagram that illustrates ultrasonic waves generated by an ultrasonic generating and receiving unit are reflected by a plurality of microcrystalline particles according to an embodiment of the present disclosure.

FIG. 5 is a diagram that illustrates ultrasonic waves reflected from a plurality of microcrystalline particles are reflected by a fingerprint according to an embodiment of the present disclosure.

FIG. 6 is a side view of an ultrasonic fingerprint identification module according to another embodiment of the present disclosure.

FIG. 7 is a top view of a display device with a fingerprint identification function according to another embodiment of the present disclosure.

FIG. 8 is a diagram that illustrates ultrasonic waves generated by an ultrasonic generating and receiving unit are reflected by a microcrystalline particle according to another embodiment of the present disclosure.

FIG. 9 is a diagram that illustrates ultrasonic waves generated by an ultrasonic generating and receiving unit are reflected by a plurality of microcrystalline particles according to another embodiment of the present disclosure.

FIG. 10 is a diagram that illustrates ultrasonic waves reflected from a plurality of microcrystalline particles are reflected by a fingerprint according to another embodiment of the present disclosure.

FIG. 11 is a side view of a display device with a fingerprint identification function according to another embodiment of the present disclosure.

### DETAILED DESCRIPTION OF PREFERRED EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure.

In the description of the present disclosure, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The disclosure herein provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

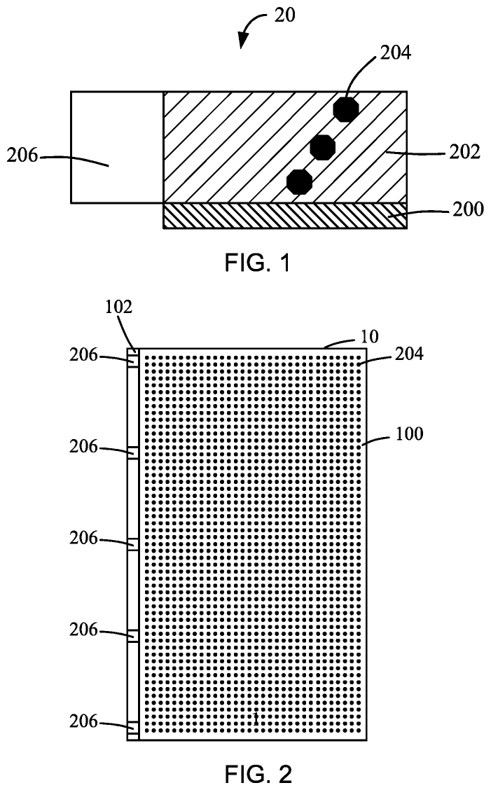

Referring to FIG. 1 and FIG. 2, FIG. 1 is a side view of an ultrasonic fingerprint identification module according to an embodiment of the present disclosure. FIG. 2 is a top view of a display device with a fingerprint identification function according to an embodiment of the present disclosure.

The display device with a fingerprint identification function includes a display panel 10 and the ultrasonic fingerprint identification module 20.

The display panel 10 includes a display area 100 and a non-display area 102.

The ultrasonic fingerprint identification module 20 includes a substrate 200, a reflecting layer 202, a plurality of microcrystalline particles (crystalline grains) 204, and at least one ultrasonic generating and receiving unit 206. The ultrasonic fingerprint identification module 20 is disposed inside an upper surface of the display device with the fingerprint identification function.

The reflecting layer 202 is disposed on the substrate 200. The reflecting layer 202 can be a hyaline layer and is made of organic materials. The organic materials can be acrylic organic materials.

The plurality of microcrystalline particles 204 are distributed and formed in the reflecting layer 202. A distribution area of the plurality of microcrystalline particles 204 correspond to the display area 100 of the display panel 10. A diameter of each of the microcrystalline particles 204 ranges between 0.01 and 3 micrometers.

It is understood that, the plurality of microcrystalline particles 204 can be made of, but is not limited to, glass. The plurality of microcrystalline particles 204 can also be made of other materials.

The at least one ultrasonic generating and receiving unit 206 is disposed on at least one side of the reflecting layer 202 and corresponds to the non-display area 102 of the display panel 10. The at least one ultrasonic generating and receiving unit 206 is configured to generate ultrasonic waves and receive ultrasonic waves.

The arrangement of the plurality of microcrystalline particles 204 can be a regular arrangement or an irregular arrangement. For example, the number of the plurality of microcrystalline particles 204 increases with increasing distance from the ultrasonic generating and receiving unit 206, or the number of the plurality of microcrystalline particles 204 decreases with increasing distance from the ultrasonic generating and receiving unit 206.

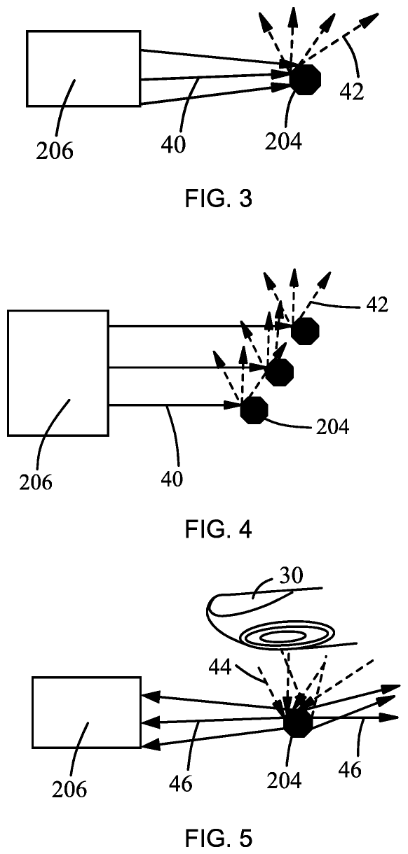

Referring to FIG. 1 to FIG. 5, FIG. 3 is a diagram that illustrates ultrasonic waves generated by the ultrasonic generating and receiving unit 206 are reflected by a microcrystalline particle 204. FIG. 4 is a diagram illustrates that ultrasonic waves generated by the ultrasonic generating and receiving unit 206 are reflected by the plurality of microcrystalline particles 204. FIG. 5 is a diagram that illustrates ultrasonic waves reflected from the plurality of microcrystalline particles 204 are reflected by a fingerprint 30.

Referring to FIG. 3 and FIG. 4, when the ultrasonic waves 40 generated by the ultrasonic generating and receiving unit 206 propagate in the reflecting layer 202 (shown in FIG. 1), a part of the ultrasonic waves 40 are reflected to the upper surface of the display panel 10 (shown in FIG. 2) by the microcrystalline particles 204. The display area 100 of the display panel 10 (shown in FIG. 2) correspond to the plurality of microcrystalline particles 204, therefore the ultrasonic waves 42 reflected from the plurality of microcrystalline particles 204 reach to the whole upper surface of the display panel 10 (shown in FIG. 2) and form an ultrasonic array on the whole upper surface of the display panel 10 (shown in FIG. 2). Referring to FIG. 5, when the fingerprint 30 touches the display panel 10 (shown in FIG. 2), a part of ultrasonic waves 44 reflected from the fingerprint 30 are reflected by the plurality of microcrystalline particles 204, then a part of ultrasonic waves 46 reflected from the plurality of microcrystalline particles 204 are reflected back to the ultrasonic generating and receiving unit 206 and form fingerprint feedback information through signal processing, then fingerprint identification is finished.

In the display device with the fingerprint identification function of the present disclosure, the ultrasonic generating and receiving unit 206 is disposed on the side of the reflecting layer 202, which decreases the thickness of the display device. Furthermore, the distribution area of the plurality of microcrystalline particles 204 correspond to the display area 100 of the display panel 10, which realizes a design of a full screen.

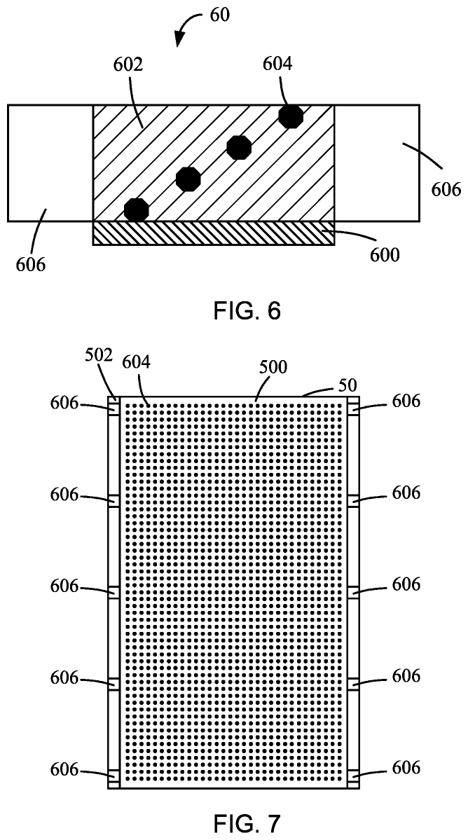

Referring to FIG. 6 and FIG. 7, FIG. 6 is a side view of an ultrasonic fingerprint identification module according to another embodiment of the present disclosure. FIG. 7 is a top view of a display device with a fingerprint identification function according to another embodiment of the present disclosure.

The display device with a fingerprint identification function includes a display panel 50 and the ultrasonic fingerprint identification module 60.

The display panel 50 includes a display area 500 and a non-display area 502.

The ultrasonic fingerprint identification module 60 includes a substrate 600, a reflecting layer 602, a plurality of microcrystalline particles 604, and a plurality of ultrasonic generating and receiving units 606. The ultrasonic fingerprint identification module 60 is disposed inside an upper surface of the display device with the fingerprint identification function.

The reflecting layer 602 is disposed on the substrate 600. The reflecting layer 602 can be a hyaline layer and is made of organic materials. The organic materials can be acrylic organic materials.

The plurality of microcrystalline particles 604 are distributed and formed in the reflecting layer 602. A distribution area of the plurality of microcrystalline particles 604 correspond to the display area 500 of the display panel 50. A diameter of each of the microcrystalline particles 604 ranges between 0.01 and 3 micrometers.

It is understood that, the plurality of microcrystalline particles 604 can be made of, but is not limited to, glass. The plurality of microcrystalline particles 604 can also be made of other materials.

The difference between the display device with the fingerprint identification function in this embodiment and the display device with the fingerprint identification function in the embodiment of FIG. 2 is that the display device with the fingerprint identification function in this embodiment includes a plurality of ultrasonic generating and receiving units 606 disposed on two sides of the reflecting layer 202. The plurality of ultrasonic generating and receiving units 606 correspond to the non-display area 502 of the display panel 50. The plurality of ultrasonic generating and receiving units 606 are configured to generate ultrasonic waves and receive ultrasonic waves.

The arrangement of the plurality of microcrystalline particles 604 can be a regular arrangement or an irregular arrangement. For example, the number of the plurality of microcrystalline particles 604 increases with increasing distance from the ultrasonic generating and receiving unit 606, or the number of the plurality of microcrystalline particles 604 decreases with increasing distance from the ultrasonic generating and receiving unit 606.

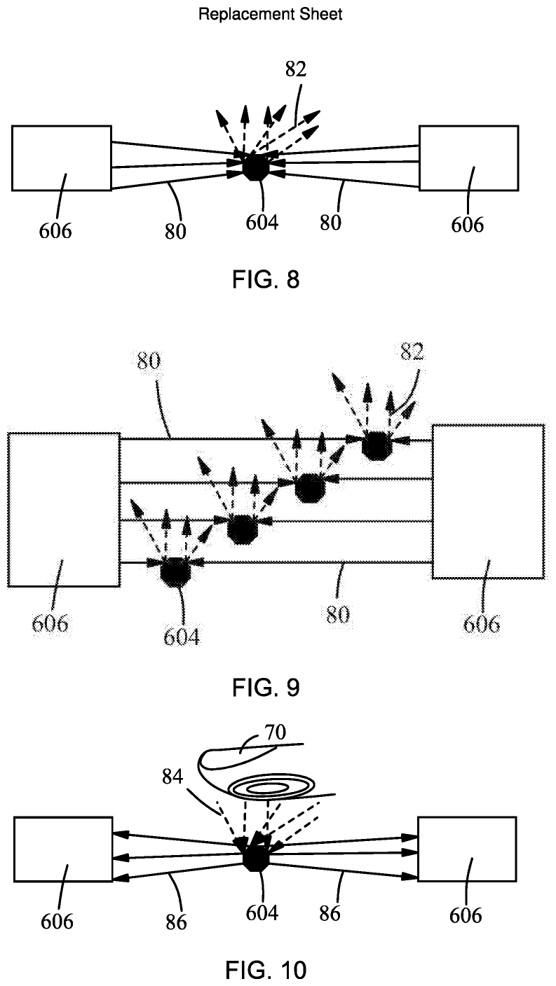

Referring to FIG. 6 to FIG. 10, FIG. 8 is a diagram that illustrates ultrasonic waves generated by the ultrasonic generating and receiving unit 606 are reflected by a microcrystalline particle 604. FIG. 9 is a diagram that illustrates ultrasonic waves generated by the ultrasonic generating and receiving unit 606 are reflected by a plurality of microcrystalline particles 604. FIG. 10 is a diagram that illustrates ultrasonic waves reflected from the plurality of microcrystalline particles 604 are reflected by a fingerprint 70.

Referring to FIG. 8 and FIG. 9, when the ultrasonic waves 80 generated by the ultrasonic generating and receiving unit 606 propagate in the reflecting layer 602 (shown in FIG. 6), a part of the ultrasonic waves 80 are reflected to the upper surface of the display panel 50 (shown in the FIG. 7) by the microcrystalline particles 604. The display area 500 of the display panel 50 (shown in FIG. 7) correspond to the plurality of microcrystalline particles 604, therefore the ultrasonic waves 82 reflected from the plurality of microcrystalline particles 604 reach to the whole upper surface of the display panel 50 (shown in FIG. 7) and form an ultrasonic array on the whole upper surface of the display panel 50 (shown in FIG. 7). Referring to FIG. 10, when the fingerprint 70 touches the display panel 50 (shown in FIG. 7), a part of ultrasonic waves 84 reflected from the fingerprint 70 are reflected by the plurality of microcrystalline particles 604, then a part of ultrasonic waves 86 reflected from the plurality of microcrystalline particles 604 are reflected back to the ultrasonic generating and receiving unit 606 and form fingerprint feedback information through signal processing, then the fingerprint identification is finished.

In the display device with the fingerprint identification function of the present disclosure, the ultrasonic generating and receiving unit 606 is disposed on the side of the reflecting layer 602, which decreases the thickness of the display device. Furthermore, the distribution area of the plurality of microcrystalline particles 604 correspond to the display area 500 of the display panel 50, which realizes a design of a full screen.

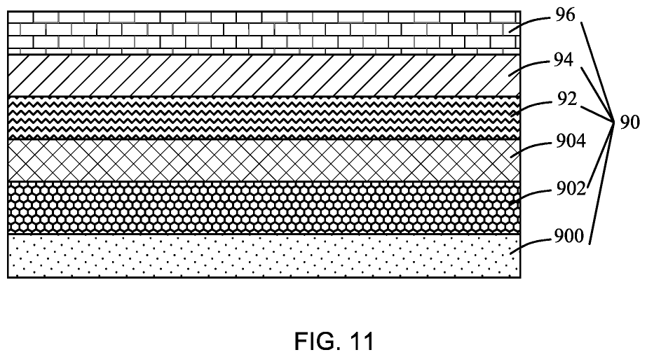

Referring to FIG. 11, FIG. 11 is a side view of a display device with a fingerprint identification function according to another embodiment of the present disclosure.

The display device with a fingerprint identification function includes a display panel 90 and an ultrasonic fingerprint identification module 92.

The ultrasonic fingerprint identification module 92 is disposed in the display panel 90. The ultrasonic fingerprint identification module 20 of FIG. 2 is disposed inside the upper surface of the display device with the fingerprint identification function. The ultrasonic fingerprint identification module 60 of FIG. 7 is also disposed inside the upper surface of the display device with the fingerprint identification function. The ultrasonic fingerprint identification module 92 in this embodiment is embedded in the display panel 90.

The display panel 90 includes a first layer 900, a second layer 902, and a touch layer 904.

The second layer 902 is disposed on the first layer 900 and configured to display an image together with the first layer 900.

In an embodiment, the first layer 900 is an array substrate, and the second layer 902 is a color filter if the display panel 90 is a liquid crystal display panel.

In another embodiment, the first layer 900 is an array substrate, and the second layer 902 is an emitting layer if the display panel 90 is an organic light emitting diode (OLED) display panel.

The touch layer 904 is disposed on the second layer 902 and configured to sense signals applying on the display panel, and the signals can be touching signals or suspended signals.

The ultrasonic fingerprint identification module 92 is disposed on the touch layer 904. The structure of the ultrasonic fingerprint identification module 92 references the relative description of FIG. 1 and FIG. 6. The ultrasonic fingerprint identification module 92 is disposed on the touch layer 904, therefore the ultrasonic fingerprint identification module 20 and 60 of FIG. 1 and FIG. 6 can omit the substrate 200 and 600 correspondingly.

Furthermore, the display device with the fingerprint identification function further includes a polarizer 94 and a protective layer 96.

The polarizer 94 is disposed on the ultrasonic fingerprint identification module 92.

The protective layer 96 is disposed on the polarizer 94.

In the display device with the fingerprint identification function of the present disclosure, the ultrasonic generating and receiving unit is disposed on the side of the reflecting layer, which decreases the thickness of the display device. Furthermore, the distribution area of the plurality of microcrystalline particles correspond to the display area of the display panel, which realizes a design of a full screen.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display device with a fingerprint identification function, comprising:
a display panel comprising a display area and a non-display area; and
an ultrasonic fingerprint identification module disposed inside an upper surface of the display device with the fingerprint identification function, comprising:
a substrate;
a reflecting layer disposed on the substrate;
a plurality of microcrystalline particles distributed in the reflecting layer; and
an ultrasonic generating and receiving unit disposed on a side of the reflecting layer;
wherein a distribution area of the plurality of microcrystalline particles correspond to the display area of the display panel, and a diameter of each of the microcrystalline particles ranges between 0.01 and 3 micrometers.

2. The display device according to claim 1, wherein the ultrasonic generating and receiving unit corresponds to the non-display area of the display panel.

3. The display device according to claim 1, further comprising a plurality of ultrasonic generating and receiving units disposed on two sides of the reflecting layer.

4. The display device according to claim 1, wherein a number of the plurality of microcrystalline particles increases with increasing distance from the ultrasonic generating and receiving unit.

5. The display device according to claim 1, wherein a number of the plurality of microcrystalline particles decreases with increasing distance from the ultrasonic generating and receiving unit.

6. A display device with a fingerprint identification function, comprising:
a display panel comprising a display area and a non-display area; and
an ultrasonic fingerprint identification module disposed inside an upper surface of the display device with the fingerprint identification function, comprising:
a substrate;
a reflecting layer disposed on the substrate;
a plurality of microcrystalline particles distributed in the reflecting layer; and
an ultrasonic generating and receiving unit disposed on a side of the reflecting layer.

7. The display device according to claim 6, wherein a distribution area of the plurality of microcrystalline particles correspond to the display area of the display panel.

8. The display device according to claim 6, wherein a diameter of each of the microcrystalline particles ranges between 0.01 and 3 micrometers.

9. The display device according to claim 6, wherein the ultrasonic generating and receiving unit corresponds to the non-display area of the display panel.

10. The display device according to claim 6, further comprising a plurality of ultrasonic generating and receiving units disposed on two sides of the reflecting layer.

11. The display device according to claim 6, a number of the plurality of microcrystalline particles increases with increasing distance from the ultrasonic generating and receiving unit.

12. The display device according to claim 6, wherein a number of the plurality of microcrystalline particles decreases with increasing distance from the ultrasonic generating and receiving unit.

13. A display device with a fingerprint identification function, comprising:
a display panel comprising a display area and a non-display area; and
an ultrasonic fingerprint identification module embedded in the display panel, comprising:
a reflecting layer disposed in the display panel;
a plurality of microcrystalline particles distributed in the reflecting layer; and
an ultrasonic generating and receiving unit disposed on a side of the reflecting layer.

14. The display device according to claim 13, wherein the display panel comprises:
a first layer;
a second layer disposed on the first layer and configured to display an image together with the first layer; and
a touch layer disposed on the second layer and configured to sense signals applying on the display panel.

15. The display device according to claim 13, further comprising:
a polarizer disposed on the ultrasonic fingerprint identification module; and
a protective layer disposed on the polarizer.
